(19) United States
(12) Patent Application Publication
(10) Pub. No.: US 2022/0367755 A1
(43) Pub. Date: Nov. 17, 2022

(54) VERTICAL DEEP-ULTRAVIOLET LIGHT-EMITTING DIODE AND METHOD FOR MANUFACTURING SAME

(71) Applicant: NANJING LIANGXIN INFORMATION TECHNOLOGY CO., LTD, Nanjing City (CN)

(72) Inventors: Yongjin WANG, Nanjing City (CN); Yuan JIANG, Nanjing City (CN)

(73) Assignee: NANJING LIANGXIN INFORMATION TECHNOLOGY CO., LTD, Nanjing City (CN)

(21) Appl. No.: 17/848,304

(22) Filed: Jun. 23, 2022

Related U.S. Application Data
(63) Continuation of application No. PCT/CN2020/128347, filed on Nov. 12, 2020.

(30) Foreign Application Priority Data
Dec. 26, 2019 (CN) 201911364817.6

(51) Int. Cl. H01L 33/32; H01L 33/38; H01L 33/62; H01L 33/40; H01L 33/00

(52) U.S. Cl. CPC H01L 33/32; H01L 33/382; H01L 33/62; H01L 33/40; H01L 33/0075; H01L 2933/0016; H01L 2933/0066

(57) ABSTRACT

The present disclosure relates to a vertical deep-ultraviolet light-emitting diode and a method for manufacturing the same. The vertical deep-ultraviolet light-emitting diode includes: a conductive substrate, wherein the conductive substrate includes a first surface and a second surface opposite to the first surface; an epitaxial layer, disposed on the first surface of the conductive substrate, and comprising a P-type GaN layer, an electron blocking layer, a quantum well layer and an N-type AlGaN layer that are successively laminated along a direction from the second surface to the first surface, wherein the epitaxial layer has a thickness less than 1 μm; an N-type electrode, disposed on a surface, facing away from the conductive substrate, of the epitaxial layer; and a P-type electrode, disposed on the second surface.

### CROSS-REFERENCE TO RELATED APPLICATIONS

This application is a continuation application of PCT application No. PCT/CN2020/128347 filed on Nov. 12, 2020, which claims priority to Chinese Patent Application No. CN201911364817.6 filed on Dec. 26, 2019, the entire disclosures thereof are incorporated herein by reference for all purposes.

### TECHNICAL FIELD

The present disclosure relates to the technical fields of illumination, display, and optical communication, and in particular, relates to a vertical deep-ultraviolet light-emitting diode and a method for manufacturing the same.

### BACKGROUND

A light emitting diode (LED) has such advantages such as small size, high efficiency, and longevity, and hence has a wide application prospect in the fields of illumination, display, and optical communication. A traditional LED uses a sapphire as a growth substrate. However, since a sapphire substrate is not conductive, the traditional LED generally uses a transverse structure with electrodes on the same side of the sapphire substrate. Such transverse structure at least has two disadvantages: one is currents transversely flow in an N-type layer in unequal distance which results in current congestion. It causes overheating in partial areas of the LED, and thus affects the device performance; the other is the heat conductivity of the sapphire is poor which limits heat dissipation of the LED device, therefore affects the longevity of the LED device. A vertical LED is present in the related art to overcome the defects of a transverse LED device.

However, a conventional vertical LED has a plurality of optical confined modes due to the limitation of the thickness of films, When electrons are passing through and lighting up the vertical LED, most of emitted light is confined within the thick film of an epitaxial layer of the LED which causes in-diaphragm transmission and absorption, such that a light-emitting efficiency of the LED is significantly reduced.

Accordingly, how to improve the wall-plug efficiency of the LED to expand the applications of the LED is a technical problem urgently to be solved.

### SUMMARY

The present disclosure provides a vertical deep-ultraviolet LED and a method for manufacturing the same, to solve the problem that a wall-plug efficiency of a deep-ultraviolet LED in the related art is low to expand the applications of the deep-ultraviolet LED.

The present disclosure provides a vertical deep-ultraviolet LED. The vertical deep-ultraviolet LED includes:

a conductive substrate, wherein the conductive substrate includes a first surface and a second surface opposite to the first surface;

an epitaxial layer, disposed on the first surface of the conductive substrate, and includes a P-type GaN layer, an electron blocking layer, a quantum well layer and an N-type AlGaN layer that are successively laminated along a direction from the second surface to the first surface, wherein the epitaxial layer has a thickness less than 1 μm;

an N-type electrode, disposed on a surface, facing away from the conductive substrate, of the epitaxial layer; and

a P-type electrode, disposed on the second surface.

The present disclosure further provides a method for manufacturing a vertical deep-ultraviolet LED. The method includes:

forming an initial epitaxial layer on a surface of a growth substrate, wherein the initial epitaxial layer comprises a buffer layer, an undoped u-AlGaN layer, an initial N-type AlGaN layer, a quantum well layer, an electron blocking layer and a P-type GaN layer that are successively laminated along a direction perpendicular to the growth substrate;

forming a conductive substrate, wherein the conductive substrate includes a first surface and a second surface opposite to the first surface;

bonding the growth substrate to the conductive substrate along a direction from the first surface to the initial epitaxial layer;

removing the growth substrate, the buffer layer and the undoped u-AlGaN layer, thinning the initial N-type AlGaN layer, taking the thinned initial N-type AlGaN layer as an N-type AlGaN layer, and forming an epitaxial layer comprising a P-type GaN layer, an electron blocking layer, a quantum well layer and the N-type AlGaN layer that are successively laminated along a direction from the second surface to the first surface, wherein the epitaxial layer has a thickness less than 1 μm; and

forming an N-type electrode on a surface, facing away from the conductive substrate, of the epitaxial layer, and forming a P-type electrode on the second surface.

### BRIEF DESCRIPTION OF THE DRAWINGS

FIG. 1 is a schematic structural view of a vertical deep-ultraviolet LED according to an embodiment of the present disclosure;

FIG. 2 is a flowchart of a method for manufacturing a vertical deep-ultraviolet LED according to an embodiment of the present disclosure; and

FIGS. 3A to 3J are schematic sectional views of processes in the manufacturing of the vertical deep-ultraviolet LED according to an embodiment of the present disclosure.

### DETAILED DESCRIPTION

Reference will now be described in detail to examples, which are illustrated in the accompanying drawings. The following description refers to the accompanying drawings in which the same numbers in different drawings represent the same or similar elements unless otherwise represented. The examples described following do not represent all examples consistent with the present disclosure. Instead, they are merely examples of devices and methods consistent with aspects of the disclosure as detailed in the appended claims.

Terms used in the present disclosure are merely for describing specific examples and are not intended to limit the present disclosure. The singular forms “one”, “the”, and “this” used in the present disclosure and the appended claims are also intended to include a multiple form, unless other meanings are clearly represented in the context. It should also be understood that the term “and/or” used in the present disclosure refers to any or all of possible combinations including one or more associated listed items.

Reference throughout this specification to “one embodiment,” “an embodiment,” “an example,” “some embodiments,” “some examples,” or similar language means that a particular feature, structure, or characteristic described is included in at least one embodiment or example. Features, structures, elements, or characteristics described in connection with one or some embodiments are also applicable to other embodiments, unless expressly specified otherwise.

It should be understood that although terms “first”, “second”, “third”, and the like are used in the present disclosure to describe various information, the information is not limited to the terms. These terms are merely used to differentiate information of a same type. For example, without departing from the scope of the present disclosure, first information is also referred to as second information, and similarly the second information is also referred to as the first information. Depending on the context, for example, the term “if” used herein may be explained as “when” or “while”, or “in response to . . . , it is determined that”.

A vertical deep-ultraviolet LED and a method for manufacturing the same according to the present disclosure are specifically described hereinafter in combination with the accompanying drawings.

According to the vertical deep-ultraviolet LED and the method for manufacturing the same of the present disclosure, an epitaxial layer including a P-type GaN layer, an electron blocking layer, a quantum well layer and an N-type AlGaN layer is formed, such that the LED is capable of emitting light of a deep-ultraviolet wavelength; and in addition, a thickness of the epitaxial layer is set to be less than 1 μm, such that a waveguide mode inside the device is effectively suppressed, the thermal effect of the device is reduced, a response speed of the device is improved, a wall-plug efficiency of the device is significantly improved, and application fields of the deep-ultraviolet LED are expanded.

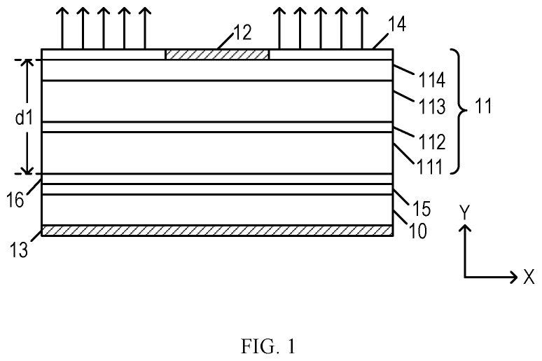

Specific embodiments of the present disclosure provide a vertical deep-ultraviolet LED. FIG. 1 is a schematic structural view of a vertical deep-ultraviolet LED according to an embodiment of the present disclosure. As illustrated in FIG. 1, the vertical deep-ultraviolet LED according to the specific embodiments includes:

a conductive substrate 10, the conductive substrate 10 including a first surface and a second surface opposite to the first surface;

an epitaxial layer 11, disposed on the first surface of the conductive substrate 10, and including a P-type GaN layer 111, an electron blocking layer 112, a quantum well layer 113 and an N-type AlGaN layer 114 that are successively laminated along a direction from the second surface to the first surface, wherein the epitaxial layer 11 has a thickness dl less than 1 μm;

an N-type electrode 12, disposed on a surface, facing away from the conductive substrate, of the epitaxial layer 11; and

a P-type electrode 13, disposed on the second surface.

To be specific, the conductive substrate 10 may be made of a metal material or a low-resistivity silicon material, which may be selected by a person skilled in the art according to actual needs. The epitaxial layer 11 includes the P-type GaN layer 111, the electron blocking layer 112, the quantum well layer 113 and the N-type AlGaN layer 114 that are successively laminated on the first surface of the conductive substrate 10 along a positive direction of an Y axis. Light of a deep-ultraviolet wavelength emitted from a side, facing away from the conductive substrate 10, of the epitaxial layer 11. That is, an arrow direction in FIG. 1 represents a direction of light emitted by the vertical deep-ultraviolet LED. The electron blocking layer 112 is a P-type electron blocking layer, and the quantum well layer 113 may be an InGaN/GaN multi-quantum well layer.

In the specific embodiments, along a direction (a Y-axis direction in FIG. 1) perpendicular to the conductive substrate 10, the N-type electrode 12 and the P-type electrode 13 are disposed on two opposite sides of the epitaxial layer 11, such that a current flows through the epitaxial layer 11 almost entirely in the direction that perpendicular to the conductive substrate (an Y-axis direction in FIG. 1), and nearly no transversely (an X-axis direction in FIG. 1) flowing current is present. In this way, an efficiency of electricity implantation is improved. Meanwhile, the thickness dl of the epitaxial layer 11 is set to be less than 1 μm, such that the vertical deep-ultraviolet LED is not subject to a confine mode (a waveguide mode) inside the vertical deep-ultraviolet LED is suppressed, transmission of light emitted by the LED inside the epitaxial layer 11 is reduced or eliminated completely, such that an absorption loss inside the device is reduced. In this way, a wall-plug efficiency of the vertical deep-ultraviolet LED is significantly improved, a thermal effect of the device is reduced, and a response speed of the device is significantly improved. Therefore, the vertical deep-ultraviolet LED may be used as a light-emitting device and a detection device in the fields of display, illumination, optical communication and the like.

Optionally, the vertical deep-ultraviolet LED further includes:

a transparent passivation layer 14, covering the surface, facing away from the conductive substrate 10, of the epitaxial layer 11;

wherein the N-type electrode 12 extends through the transparent passivation layer 14 along a direction perpendicular to the conductive substrate 10, and is in contact with the N-type AlGaN layer 114.

Optionally, the transparent passivation layer 14 is made of silicon dioxide; and

the transparent passivation layer 14 is arranged as surrounding a periphery of the N-type electrode 12.

To be specific, the light is emitted outwards from the transparent passivation layer 14. By arranging the transparent passivation layer 14 covering the N-type AlGaN layer 114, bulk etching (that is, formation of a step structure) of the epitaxial layer 11 during manufacturing of the vertical deep-ultraviolet LED is prevented, a manufacturing process of the vertical deep-ultraviolet LED is simplified, and a yield of the vertical deep-ultraviolet LED is improved; and in addition, an entire light-emitting area of the vertical deep-ultraviolet LED is increased, such that a light-emitting efficiency of the deep-ultraviolet LED is further enhanced. A person skilled in the art may select other transparent insulative materials to form the transparent passivation layer 14 according to actual needs.

Optionally, the vertical deep-ultraviolet LED further includes:

a metal bonding layer 15, disposed on the first surface;

a metal reflective layer 16, bonded to a surface, facing away from the conductive substrate 10, of the metal bonding layer 15, wherein the epitaxial layer 11 is disposed on a surface of the metal reflective layer 16.

Optionally, the metal bonding layer 15 is made of a tin-gold alloy or an indium metal, and the metal reflective layer 16, the P-type electrode 13 and the N-type electrode 12 are all made of one of titanium, platinum and gold, or a combination of two or more thereof. For example, the metal reflective layer 16 may be made of an alloy of titanium, platinum and gold, and the metal bonding layer 15 may be made of indium.

To be specific, the metal bonding layer 15 is bonded to the metal reflective layer 16, such that the epitaxial layer 11 may be grown on any suitable surface of the growth substrate and then transferred to the conductive substrate 10. With the metal reflective layer 16, the emitted light may be reflected, such that a light loss is reduced, and a light-emitting efficiency of the vertical deep-ultraviolet LED is further improved.

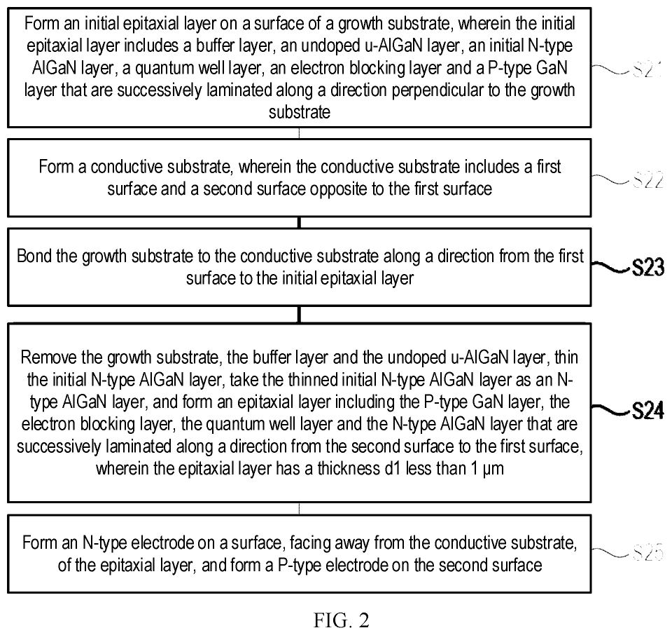

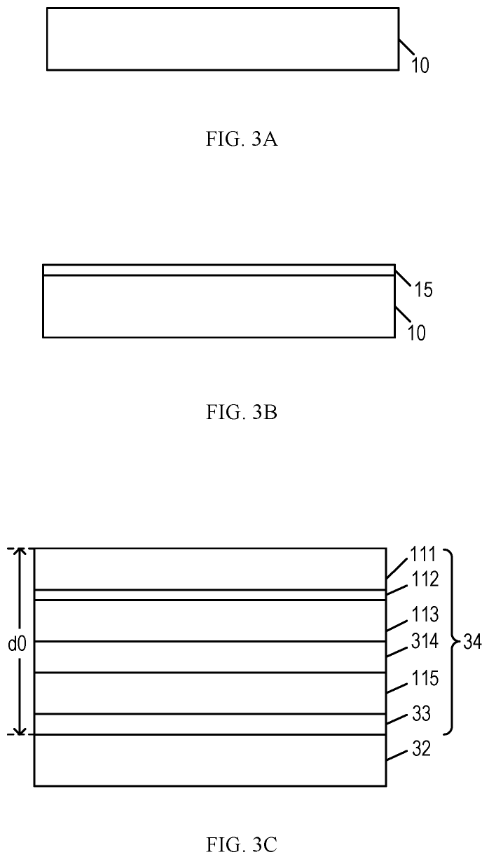

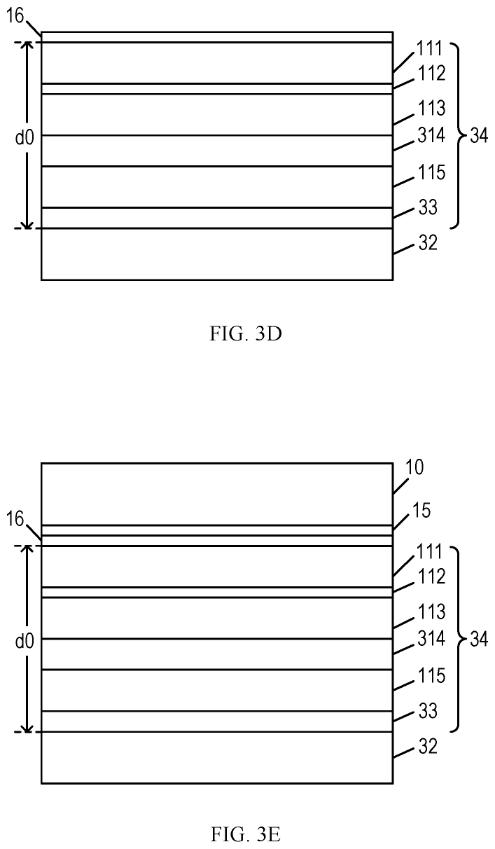

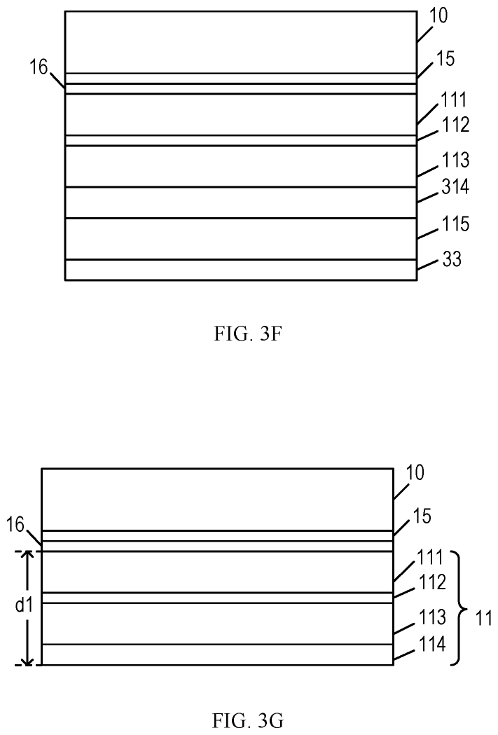

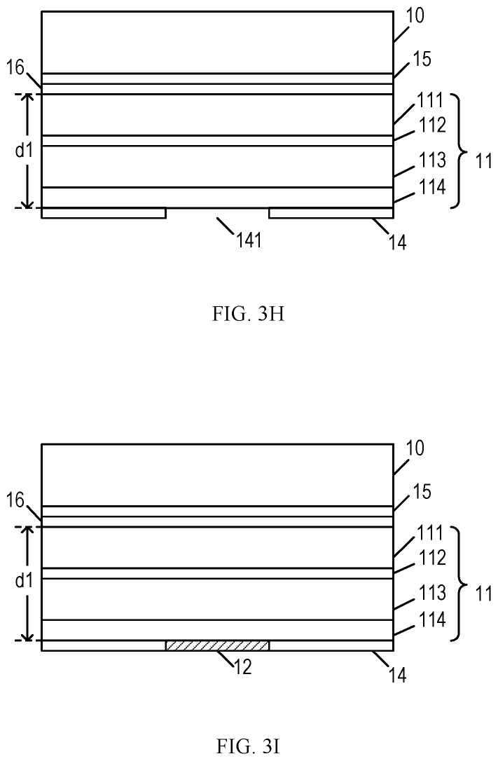

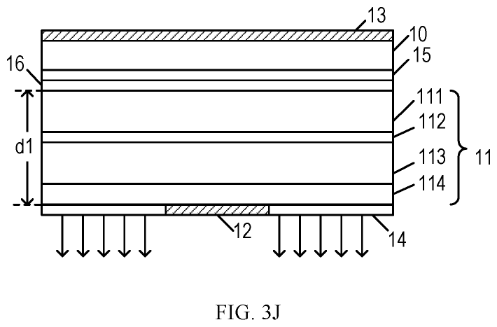

In addition, the specific embodiments further provide a method for manufacturing a vertical deep-ultraviolet LED. FIG. 2 is a schematic flowchart of a method for manufacturing a vertical deep-ultraviolet LED according to an embodiment of the present disclosure. FIG. 3A to FIG. 3J are schematic sectional views of processes in the manufacturing of the vertical deep-ultraviolet LED according to an embodiment of the present disclosure. A specific structure of the vertical deep-ultraviolet LED manufactured according to the embodiment is as illustrated in FIG. 1. As illustrated in FIG. 1 and FIG. 2, and FIG. 3A to FIG. 3J, the method for manufacturing the vertical deep-ultraviolet LED according to the specific embodiments includes the following steps:

In step S21, an initial epitaxial layer 34 is formed on a surface of a growth substrate 32, wherein the initial epitaxial layer 34 includes a buffer layer 33, an undoped u-AlGaN layer (undoped AlGaN layer) 115, an initial N-type AlGaN layer 314, a quantum well layer 113, an electron blocking layer 112 and a P-type GaN layer 111 that are successively laminated along a direction perpendicular to the growth substrate 32, as illustrated in FIG. 3C.

Optionally, forming the initial epitaxial layer 34 on the surface of the growth substrate 32 includes:

providing the growth substrate 32; and

forming the initial epitaxial layer 34 by successively depositing the buffer layer 33, the undoped u-AlGaN layer 115, the initial N-type AlGaN layer 314, the quantum well layer 113, the electron blocking layer 112 and the P-type GaN layer 111 along the direction perpendicular to the growth substrate 32, wherein the initial epitaxial layer 34 has a thickness d0 greater than a wavelength of light emitted by the vertical deep-ultraviolet LED.

To be specific, the growth substrate 32 may be a III-V class material substrate, a sapphire substrate, or a silicon substrate, which may be selected by a person skilled in the art according to actual needs. In the specific embodiments of the present disclosure, the growth substrate 32 is preferably a sapphire substrate. The buffer layer 33 is configured to reduce a stress between the growth substrate 32 and the undoped u-AlGaN layer 115. A person skilled in the art may select a specific material of the buffer layer 33 according to actual needs, for example, an AlN material.

In step S22, a conductive substrate 10 is formed, wherein the conductive substrate 10 includes a first surface and a second surface opposite to the first surface, as illustrated in FIG. 3A.

To be specific, the conductive substrate 10 may be made of a metal material or a low-resistivity silicon material, which may be selected by a person skilled in the art according to actual needs. In the specific embodiments of the present disclosure, the conductive substrate 10 is preferably a low-resistivity silicon substrate.

In step S23, the growth substrate 32 is bonded to the conductive substrate 10 along a direction from the first surface to the initial epitaxial layer 34, as illustrated in FIG. 3E.

Optionally, bonding the growth substrate 32 to the conductive substrate 10 along the direction from the first surface to the initial epitaxial layer 34 specifically includes:

forming a metal bonding layer 15 on the first surface, as illustrated in FIG. 3B;

forming a metal reflective layer 16 on a surface, facing away from the growth substrate 32, of the initial epitaxial layer 34, as illustrated in FIG. 3D; and

bonding the metal bonding layer 15 to the metal reflective layer 16, as illustrated in FIG. 3E.

To be specific, during bonding of the growth substrate 32 to the conductive substrate 10, the bonding is implemented by facing the metal bonding layer 15 towards the metal reflective layer 16. Since the metal bonding layer 15 and the metal reflective layer 16 are both made of a metal material, bonding strength between the growth substrate 32 and the conductive substrate 10 is enhanced.

In step S24, the growth substrate 32, the buffer layer 33 and the undoped u-AlGaN layer 115 are removed, the initial N-type AlGaN layer 314 is thinned, the thinned initial N-type AlGaN layer 314 is taken as an N-type AlGaN layer 114, and an epitaxial layer 11 including the P-type GaN layer 111, the electron blocking layer 112, the quantum well layer 113 and the N-type AlGaN layer 114 that are successively laminated along a direction from the second surface to the first surface is formed, wherein the epitaxial layer 11 has a thickness dl less than 1 μm, as illustrated in FIG. 3G.

To be specific, in the case that the growth substrate 32 is bonded to the conductive substrate 10, first, the growth substrate 32 is removed (stripped) by a grinding and polishing process forming a structure as illustrated in FIG. 3F; afterwards, the buffer layer 33 and the undoped u-AlGaN layer 115 are further removed, and the initial N-type AlGaN layer 314 is thinned, such that the thickness dl of the formed epitaxial layer 11 is less than 1 μm, as illustrated in FIG. 3G.

In step S25, an N-type electrode 12 is formed on a surface, facing away from the conductive substrate 10, of the epitaxial layer 11, and a P-type electrode 13 is formed on the second surface, as illustrated in FIG. 3J.

Optionally, forming the N-type electrode 12 on the surface, facing away from the conductive substrate 10, of the epitaxial layer 11 specifically includes:

forming a transparent passivation layer 14 on the surface, facing away from the conductive substrate 10, of the epitaxial layer 11, wherein the transparent passivation layer 14 includes a window 141 configured to expose the N-type AlGaN layer 114, as illustrated in FIG. 3H; and

forming the N-type electrode 12 in contact with the N-type AlGaN layer 114 in the window 141, as illustrated in FIG. 3I.

Optionally, the transparent passivation layer 14 is made of silicon dioxide; and

the transparent passivation layer 14 is arranged as surrounding a periphery of the N-type electrode 12.

To be specific, in the case that the transparent passivation layer 14 is grown on a surface of the N-type AlGaN layer 114, the window 141 is defined and formed in the transparent passivation layer, as illustrated in FIG. 3H; afterwards, the N-type electrode 12 is vapor-deposited on the window 141, as illustrated in FIG. 3I; then, the conductive substrate 10 is thinned to a thickness required for packaging the device, and the P-type electrode 13 is vapor-deposited on a surface, facing away from the epitaxial layer 11, of the conductive substrate 10, as illustrated in FIG. 3J.

In other specific embodiments, the transparent passivation layer 14 may not be formed, and instead, the N-type electrode 12 may be directly deposited on the N-type AlGaN layer 114.

According to the vertical deep-ultraviolet LED and the method for manufacturing the same of the specific embodiments of the present disclosure, an epitaxial layer including a P-type GaN layer, an electron blocking layer, a quantum well layer and an N-type AlGaN layer is formed, such that the LED is capable of emitting light of a deep-ultraviolet wavelength; and in addition, a thickness of the epitaxial layer is defined to be less than a wavelength of light emitted by the device, such that a waveguide mode inside the device is effectively suppressed, a thermal effect of the device is reduced, a response speed of the device is improved, a wall-plug efficiency of the device is significantly enhanced, and application fields of the deep-ultraviolet LED are expanded.

Described above are preferred examples of the present disclosure. It should be noted that persons of ordinary skill in the art may derive other improvements or polishments without departing from the principles of the present disclosure. Such improvements and polishments shall be deemed as falling within the protection scope of the present disclosure.

What is claimed is:

1. A vertical deep-ultraviolet light-emitting diode, comprising:
a conductive substrate, wherein the conductive substrate comprises a first surface and a second surface opposite to the first surface;
an epitaxial layer, disposed on the first surface of the conductive substrate, and comprising a P-type GaN layer, an electron blocking layer, a quantum well layer and an N-type AlGaN layer, wherein the P-type GaN layer, the electron blocking layer, the quantum well layer and the N-type AlGaN layer are successively laminated along a direction from the second surface to the first surface, and a thickness of the epitaxial layer is less than 1 μm;
an N-type electrode, disposed on a surface, facing away from the conductive substrate, of the epitaxial layer; and
a P-type electrode, disposed on the second surface.

2. The vertical deep-ultraviolet light-emitting diode according to claim 1, further comprising:
a transparent passivation layer, covering the surface, facing away from the conductive substrate, of the epitaxial layer;
wherein the N-type electrode extends through the transparent passivation layer along a direction perpendicular to the conductive substrate, and is in contact with the N-type AlGaN layer.

3. The vertical deep-ultraviolet light-emitting diode according to claim 2, wherein the transparent passivation layer is made of silicon dioxide; and
the transparent passivation layer is arranged as surrounding a periphery of the N-type electrode.

4. The vertical deep-ultraviolet light-emitting diode according to claim 1, further comprising:
a metal bonding layer, disposed on the first surface; and
a metal reflective layer, bonded to a surface, facing away from the conductive substrate, of the metal bonding layer, wherein the epitaxial layer is disposed on a surface of the metal reflective layer.

5. The vertical deep-ultraviolet light-emitting diode according to claim 1, wherein the metal bonding layer is made of a tin-gold alloy or an indium metal, and the metal reflective layer, the P-type electrode and the N-type electrode are all made of one of titanium, platinum or gold or a combination of two or more thereof.

6. A method for manufacturing a vertical deep-ultraviolet light-emitting diode, comprising:
forming an initial epitaxial layer on a surface of a growth substrate, wherein the initial epitaxial layer comprises a buffer layer, an undoped u-AlGaN layer, an initial N-type AlGaN layer, a quantum well layer, an electron blocking layer and a P-type GaN layer that are successively laminated along a direction perpendicular to the growth substrate;
forming a conductive substrate, wherein the conductive substrate includes a first surface and a second surface opposite to the first surface;
bonding the growth substrate to the conductive substrate along a direction from the first surface to the initial epitaxial layer;
removing the growth substrate, the buffer layer and the undoped u-AlGaN layer, thinning the initial N-type AlGaN layer, taking the thinned initial N-type AlGaN layer as an N-type AlGaN layer, and forming an epitaxial layer comprising a P-type GaN layer, an electron blocking layer, a quantum well layer and the N-type AlGaN layer that are successively laminated along a direction from the second surface to the first surface, wherein a thickness of the epitaxial layer is less than 1 μm; and
forming an N-type electrode on a surface, facing away from the conductive substrate, of the epitaxial layer, and forming a P-type electrode on the second surface.

7. The method according to claim 6, wherein forming the initial epitaxial layer on the surface of the growth substrate comprises:
providing the growth substrate; and
forming, on the surface of the growth substrate, the initial epitaxial layer by successively depositing the buffer layer, the undoped u-AlGaN layer, the initial N-type AlGaN layer, the quantum well layer, the electron blocking layer and the P-type GaN layer along the direction perpendicular to the growth substrate, wherein the initial epitaxial layer has a thickness greater than a wavelength of light emitted by the vertical deep-ultraviolet light-emitting diode.

8. The method according to claim 6, wherein bonding the growth substrate to the conductive substrate along the direction from the first surface to the initial epitaxial layer comprises:
forming a metal bonding layer on the first surface;
forming a metal reflective layer on a surface, facing away from the growth substrate, of the initial epitaxial layer; and
bonding the metal bonding layer to the metal reflective layer.

9. The method according to claim 6, wherein forming the N-type electrode on the surface, facing away from the conductive substrate, of the epitaxial layer comprises:
forming a transparent passivation layer on a surface, facing away from the conductive substrate, of the epitaxial layer, wherein the transparent passivation layer comprises a window configured to expose the N-type AlGaN layer; and
forming the N-type electrode in contact with the N-type AlGaN layer in the window.

10. The method according to claim 9, wherein the transparent passivation layer is made of silicon dioxide; and
the transparent passivation layer is arranged as surrounding a periphery of the N-type electrode.
